(19) United States
(12) Patent Application Publication
(10) Pub. No.: US 2002/0075046 A1
(43) Pub. Date: Jun. 20, 2002

(54) Power-on reset circuit with voltage sensing functions

(76) Inventors: Her-Y Shih, Hsin-Chu (TW); Jean-Ming Lee, Hsin-Chu (TW); Chu-Chiao Yu, Hsin-Chu (TW)

Correspondence Address: BACON & THOMAS, 4th Floor, 625 Slaters Lane, Alexandria, VA, 22314, US

(21) Appl. No.: 09/737,481

(22) Filed: Dec. 18, 2000

(51) Int. Cl. H03L 7/00

(52) U.S. Cl. 327/143

(57) ABSTRACT

A power-on reset circuit with voltage sensing functions is provided. The invented power-on reset circuit comprises a power voltage sensing circuit and a delay circuit, and an inverter between them. When the supplied power is ON, the power-on reset circuit generates a reset signal. When the voltage of the supplied power is above a predetermined level, the power voltage sensing circuit generates a sensing signal. The sensing signal is input to the delay circuit to generate a delay effect. After a predetermined period of time from the sensing signal, the reset signal is disabled. In addition, when a sudden drop in the supplied power is sensed, a reset signal is generated immediately. Errors in the operation of the circuit may thus be avoided.

### FIELD OF INVENTION

The present invention relates to a power-on reset circuit, especially to a power-on reset circuit with voltage sensing functions.

### BACKGROUND OF INVENTION

The power-on reset circuit is a component used in almost all application circuits. The functions of the power-on reset circuit is to reset all related circuits upon the power-on operation of the circuits, such that the related circuits may be operable. In addition, when there is a sudden drop in the power source, all circuits shall be reset again. At the initial stage of a power-on operation, the voltage increases in an increasing curve. The reset must be started when the voltage of the power is above a certain level. To achieve such a purpose, a voltage sensing function to sense the voltage of the supplied power may be provided in the power-on reset circuit.

In the conventional art, the timing of the reset is controlled by a delay circuit comprising resistances and capacitors. FIG. 1 shows the circuit diagram of a conventional power-on reset circuit. This figure is abstracted from U.S. Pat. No. 4,717,840. In this design, the power-on reset circuit has a CMOS pair output section and a capacitor coupling with the gate of the CMOS transistor. When the supplied power is ON, POR generates a reset signal. At the same time, the capacitor begins to be charged until the reset operation is completed, whereby the reset signal turns to a lower level. In this power-on reset circuit, in order to avoid problems caused by the slow ramping of the supplied power, a voltage sensing switch is provided. This voltage sensing switch stops the capacitor from being charged before the voltage of the supplied power reaches a predetermined level. In addition, in order to avoid problems caused by the rapid ramping of the supplied power, the charging rate of the capacitor is controlled, such that the delay time of the reset signal may be as long as or longer than a predetermined period.

Although the above-said power-on reset circuit is able to provide accurate control of the delay time of the reset operation, it has several drawbacks. First of all, in the above-said circuit, in order to provide a delay time for about tens of microseconds, a relatively large space in the circuit is used by the capacitor. As a result, the area of the total circuit is unnecessarily expanded and costs in preparing the circuit is thus increased. Secondly, although the circuit provides a voltage sensing circuit, such a circuit is not able to generate a reset signal to reset the circuits, when there is a sudden drop in the voltage of the supplied power. Normal operation of the circuit can not be ensured.

It is thus necessary to provide a power-on reset circuit with voltage sensing functions.

It is also necessary to provide a power-on reset circuit that is sensitive to variations of voltage of supplied power.

It is also necessary to provide a simplified but accurate power-on reset circuit.

### OBJECTIVES OF INVENTION

The objective of this invention is to provide a novel power-on reset circuit.

Another objective of this invention is to provide a power-on reset circuit with voltage sensing functions.

Another objective of this invention is to provide a power-on reset circuit that reset circuits accurately according to the variation of voltage of supplied power.

Another objective of this invention is to provide a simplified but accurate power-on reset circuit.

### SUMMARY OF INVENTION

According to this invention, a power-on reset circuit with voltage sensing functions is provided. The power-on reset circuit of this invention comprises a power voltage sensing circuit and a delay circuit, and an inverter therebetween. When the supplied power is ON, the power-on reset circuit generates a reset signal. When the voltage of the supplied power is above a predetermined level, the power voltage sensing circuit generates a sensing signal. The sensing signal is input to the delay circuit to generate a delay effect. After a predetermined period of time from the sensing signal, the reset signal is disabled. In addition, when a sudden drop in the supplied power is sensed, a reset signal is generated immediately. Errors in the operation of the circuit may thus be avoided.

These and other objectives and advantages of this invention may be clearly understood from the detailed description by referring to the following drawings.

### BRIEF DESCRIPTION OF DRAWINGS

FIG. 1 illustrates the circuit diagram of a conventional power-on reset circuit.

FIG. 2 illustrates the circuit diagram of an embodiment of the power-on reset circuit of this invention.

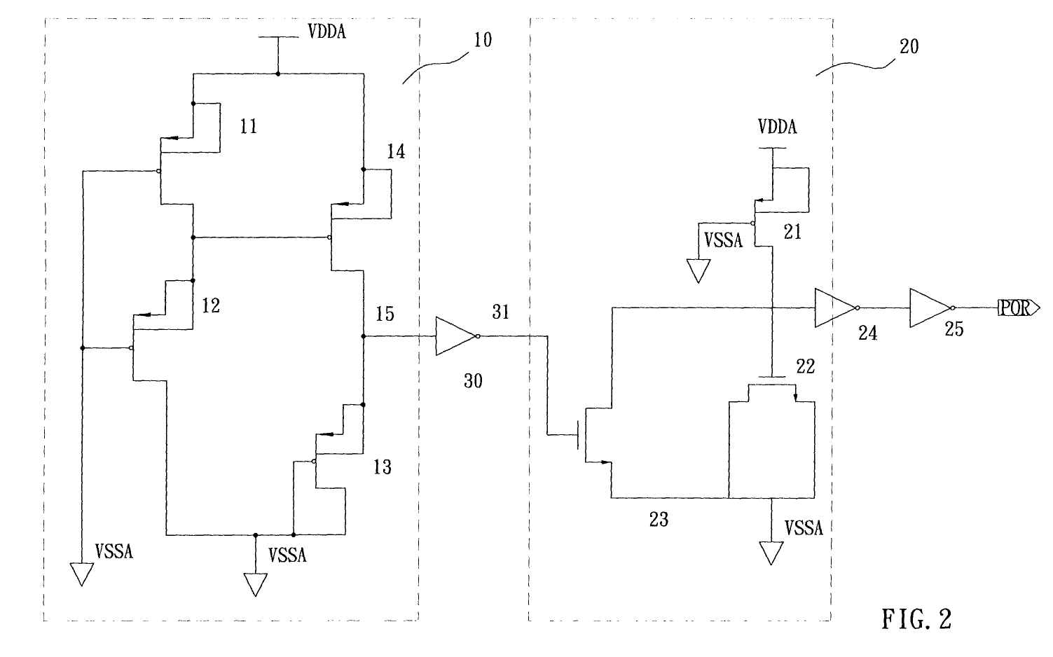

FIG. 3 shows the result of the reset operation of the power-on reset circuit of this invention, as simulated by a computer software.

### DETAILED DESCRIPTION OF INVENTION

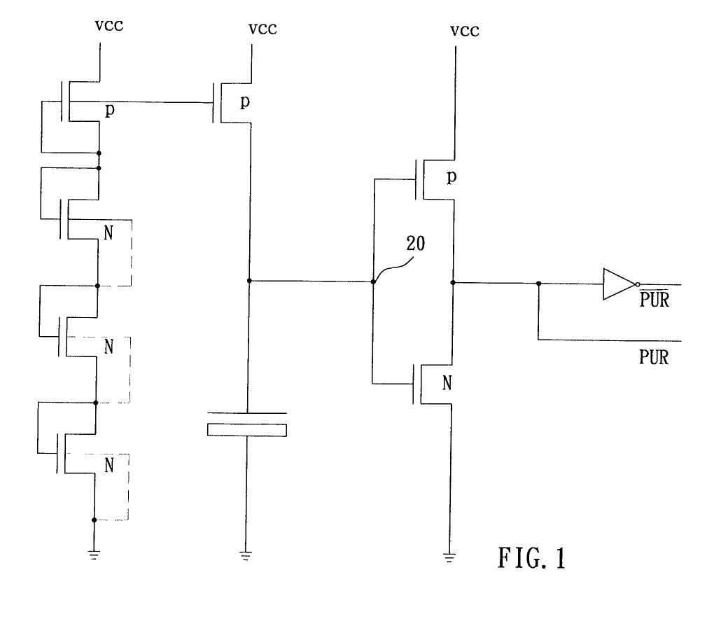

The following is a detailed description of the power-on reset circuit of this invention. FIG. 1 illustrates the circuit diagram of the power-on reset circuit of this invention.

As shown in this figure, the power-on reset circuit of this invention comprises a voltage sensing circuit 10 and a delay circuit 20, and an inverter 30 between the voltage sensing circuit 10 and the delay circuit 20.

The voltage sensing circuit 10 comprises 4 PMOS transistor 11, 12, 13 and 14. VDD represents the power supply and VSS represents the earth. On the other hand, the delay circuit 20 comprises a first transistor 21, a capacitor 22, a second transistor 23 and an inverter 24 at the next stage of the second transistor 23. POR represents the output of the power-on reset circuit. The power voltage sensing circuit 10 connects the inverter 30 at a sensing position 15. The inverter 30, in turn, connects the delay circuit 20 at position 31.

In this embodiment, the capacitor 22 may be a NMOS transistor. In other embodiments, other forms of capacitors may also apply.

The operation of the power-on reset circuit of this invention is illustrated as follows:

When the voltage of the power VDD increases from 0V gradually, because of the operation of the PMOS transistors 11, 12, 13 and 14, a sensing signal will not be generated by the voltage sensing circuit 10 until the voltage at the sensing position 15 is equal to or greater than the threshold value VTH of the inverter 30. The sensing signal is a low level signal. According to this embodiment, when the voltage at the sensing position 31 is low, the second transistor 23 is OFF, such that the first transistor 31 starts to charge the capacitor 22. On the other hand, when the voltage at the sensing position 31 is high, the second transistor 23 is OFF. As a result, a reset signal is generated at POR. At the same time, in the delay circuit 20, a delay effect is generated when the first transistor 21 starts to charge the capacitor 22. After a predetermined charging time period, POR generates a high level signal to disable the reset signal.

When the voltage of the supplied power is dropped suddenly, because of the operation of the PMOS transistors 11, 12, 13 and 14, the voltage at the sensing position 15 drops rapidly. As a result, the output of the inverter 30, i.e., the voltage at position 31, is high. At this time point, through the operation of the second transistor 23, a low level signal is generated by POR simultaneously. This low level signal functions as a reset signal. Since the second transistor 23 is ON, the first transistor 31 is stopped from charging the capacitor 22 until when the voltage of the supplied power is increased to over said threshold value VTH. After the voltage of the power is greater than the threshold value VTH, the voltage at position 31 turns to be low, whereby the first transistor 21 starts to charge the capacitor 22. After a predetermined delay time, the reset signal is disabled according to the operation as described above.

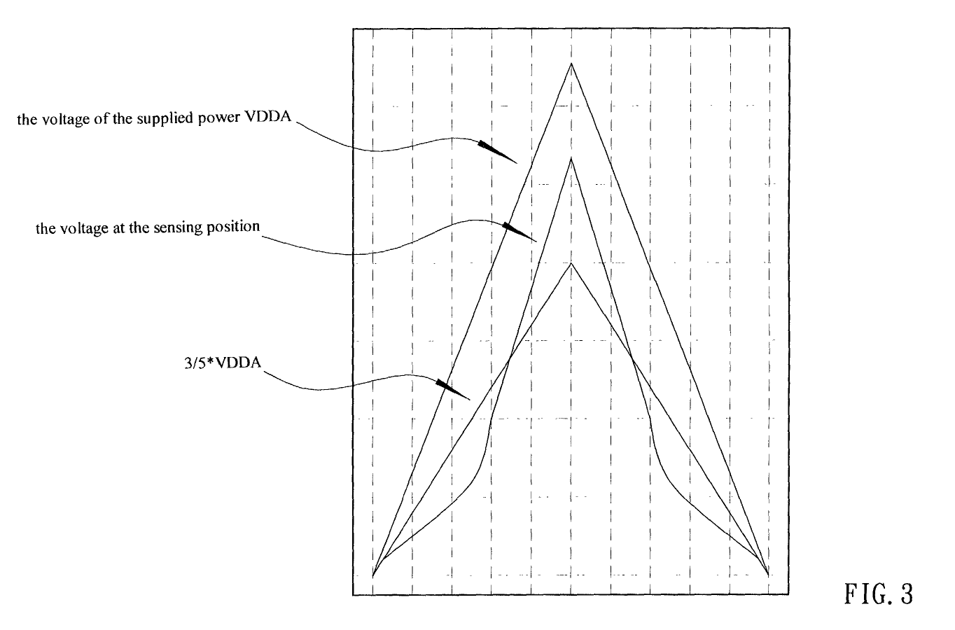

Use a computer software to simulate the operation of the power-on reset circuit of this invention. The result shows that in a circuit of 3.3V power voltage, supposing the threshold value VTH of the inverter 30 is ⅗VDD, when the voltage of the supplied power is increased from 0V to 3.3V the voltage curve of the sensing position 15 and that of the ⅗VDD will have one crossing is the increasing section and in the decreasing section. FIG. 3 illustrates the result of the reset operation of the power-on reset circuit of this invention, as simulated by a computer software.

As described above, the power-on reset circuit of this invention employs a simplified circuit to generate a reset signal with sufficient duration upon the power-on of the circuit. When the voltage of the supplied power drops suddenly, a reset signal may be generated rapidly. Errors in the operation of the circuit may thus be avoided. Due to the simplified circuit design of this invention, preparation cost of the power-on reset circuit may be saved. In addition, in the power-on reset circuit of this invention, it is not necessary to provide a large space in order to achieve sufficient delay time.

As the present invention has been shown and described with reference to preferred embodiments thereof, those skilled in the art will recognize that the above and other changes may be made therein without departing form the spirit and scope of the invention.

What is claimed is:

1. A power-on reset circuit comprising:
a reset signal generating circuit to generate a reset signal at the power-on of a power supply;
a voltage sensing circuit to generate a first sensing signal when voltage of power supplied by said power supply is equal to or higher than a first predetermined level and a second sensing signal when voltage of power supplied by said power supply is equal or lower than a second predetermined level; and
a time delay circuit to generate a reset disable signal after a predetermined duration from when said voltage sensing circuit generates said first sensing signal;
characterized in that said reset signal generating circuit generates a reset signal when said second sensing signal is generated by said voltage sensing circuit.

2. The power-on reset circuit according to claim 1 wherein said voltage sensing circuit comprises two PMOS transistor arrays parallel to said power supply.

3. The power-on reset circuit according to claim 1 wherein said delay time circuit comprises a PMOS transistor and a capacitor controlled by said PMOS transistor.
